(19) United States
(12) Patent Application Publication
(10) Pub. No.: US 2017/0069467 A1
(43) Pub. Date: Mar. 9, 2017

(54) PLASMA-BASED PROCESSING SYSTEM AND OPERATION METHOD THEREOF

(71) Applicant: ADVANCED ION BEAM TECHNOLOGY, INC., Hsin-Chu (TW)

(72) Inventors: Wei-Cheng Lin, Hsinchu City (TW); Yoko Kawai Parker, HSIN-CHU (TW); Tienyu Sheng, HSIN-CHU (TW)

(21) Appl. No.: 15/254,265

(22) Filed: Sep. 1, 2016

(30) Foreign Application Priority Data
Sep. 4, 2015 (TW) 104129436

(51) Int. Cl. H01J 37/32; C23C 16/50; C23C 14/34

(52) U.S. Cl. CPC H01J 37/32422; C23C 14/34; C23C 16/50; H01J 37/32715; H01J 2237/334; H01J 2237/3321

(57) ABSTRACT

A plasma-based processing system and a corresponding operation method are proposed. One or more absorbers are positioned between a plasma generation volume inside the plasma chamber and a support structure configured to support the workpiece, and then a portion of plasma delivered from the plasma generation volume to the support structure (or the workpiece) is absorbed by the absorber(s). Further, the absorber(s) are made of electrical conductive material(s), and the structure of at least one absorber and/or the relative geometric relation between at least two absorbers is adjustable. Hence, the position(s) of the electric conductor(s) overlap(s) with the delivered plasma may be adjusted, and then the ion current distribution on the cross section of the delivered plasma may be modified correspondingly.

### CROSS-REFERENCE TO RELATED APPLICATIONS

The entire contents of Taiwan Patent Application No. 104129436, filed on Sep. 4, 2015, from which this application claims priority, are incorporated herein by reference.

### BACKGROUND OF THE INVENTION

1. Field of the Invention

The present invention generally relates to a plasma-based processing system and an operation method thereof, and more particularly for using at least one absorber made of electrical conductive material, and the structure and/or relative position of the at least one absorber is adjustable, in order that the ion current distribution on the cross section of the plasma delivered to the workpiece and/or the support structure, may be modified correspondingly.

2. Description of Related Art

The plasma-based processing system and the operation method thereof are important parts of the modern high-tech industry, whether it is applied to the integrated circuit element, the liquid crystal panel, the light emitting diode, the memory or the others. The applications of the plasma processing system and operation method thereof at least include, but are not limited to, transforming the surface of one workpiece from a crystalline material into a non-crystalline material, removing some material from the workpiece, introducing some impurities into the workpiece, forming new material on the surface or in the surface layer, and changing the physical/chemical/electrical properties of the surface or surface layer of the workpiece.

For example, the ion-based material modification is also an important part of the manufacturing process of the semiconductor element and other modern elements. The beam-line ion implantation system, which is currently widely used, often encounters the problem of low ion beam current amount in the low-energy process, which requires a longer processing time to achieve a dose level which a low energy ion process needs, and the cross-sectional area of the provided ion beam is often significantly less than the surface area of the pending workpiece, so that it is often that only a small part of the entire workpiece can be modified at one time. As a result, the ion beam ion implantation systems in the high-dose and low-energy procedures are often faced with the problem of low capacity. Thus, in recent years, another approach for achieving base material modification is one of plasma-base processing systems: plasma-based material modification systems.

In addition to the plasma-based material modification system, the plasma-based processing system further includes, but is not limited to, the plasma etcher, the sputter system and the plasma enhanced chemical vapor deposition system. Although the structures and the operation methods in the different plasma-based processing systems are different from one other, as shown in FIG. 1, the basic framework of the plasma-based processing system at least includes a plasma chamber 102 which is configured to generate plasma, and a support structure 104 which is configured to support a workpiece 112. Herein, the support structure 104 not only can be positioned outside the plasma chamber 102, but also can be positioned inside the plasma chamber 102 or positioned on the edge of the plasma chamber 102. The plasma 114, generated in the plasma chamber 102, includes a great number of ions, electrically neutral particles and electrons, which are able to be delivered from the plasma generation volume of the plasma chamber 102 to the workpiece 112 and/or the support structure 104.

Apparently, it is usual that the plasma 114 is directly delivered from the ion-generating space of the plasma chamber to the workpiece 112 which is not far away, and the plasma 114 formed in the plasma chamber 102 can often has a larger cross sectional area than does the workpiece 112. Thus, it not only can often provide a large quantity of ion current onto the workpiece 102, but also often can deal well with the whole or at least most of the workpiece 102. Thus, a branch plasma base material modification system of the plasma-based processing system may effectively provide high capacity in the high-dose and low-energy procedures, which a beamline ion implantation system cannot achieve.

However, prior art plasma-based processing systems still have some disadvantages which lead to the problems of poor system reliability, imprecise process control and the like. For example, as the interaction of the plasma 114 with the plasma chamber 102 proceeds, ions, electrons or conductive particles of plasma 114 may collide with the chamber wall of the plasma chamber 102. This in turn results in the uneven distribution of the plasma 114, wherein the density of plasma is higher in the central portion as compared to its peripheral portions. For example, there might be occasions when the gases and energy are unevenly distributed in the plasma chamber 102. This, in conjunction with a continual failure to completely and precisely control of the operation of plasma chamber 102, could lead to numerous distributions of plasma 114 within the plasma chamber 102. As a result, the interaction between the plasma 114 and the workpiece 112 onto which the plasma 114 is delivered varies a lot.

Thus, it is required to develop a new system and/or method to reduce and/or solve the problems of unevenness and fluctuation of plasma distribution in the current plasma-based processing system.

### SUMMARY OF THE INVENTION

The present invention provides a plasma-based processing system, including a plasma chamber configured to generate plasma, a support structure configured to support a workpiece, and at least one absorber made of electrical conductive material, and the structure and/or relative geometric relation of the at least one absorber is adjustable. The system may further include a measuring device configured to measure the plasma. Herein, the measuring device is configured to measure the plasma delivered from the plasma generation volume, between the plasma generation volume inside the plasma chamber and the support structure. Hence, by adjusting the absorber, such as performing the adjustment according to the measurement result of the measuring device, the distribution of the plasma delivered from the plasma generation volume to the workpiece and/or support structure can be modified.

The present invention provides an operation method using a plasma-based processing system. Firstly, plasma is generated in a plasma generation volume inside the plasma chamber; then, using measuring device, between the plasma generation volume and the support structure (or workpiece), to measure the plasma delivered from the plasma generation volume to the support structure (or workpiece); adjusting at least one absorber positioned between the plasma generation volume and the support structure (or workpiece), according to a measurement result from the measuring device; and at last, using the at least one absorber, which is adjusted, to absorb at least a portion of the plasma delivered to the support structure (or workpiece). The material of any one absorber is electrically conductive material, and the structure and/or relative geometric relation of the absorbers are adjustable. Of course, if the adjustment for delivered plasma is scheduled, then the measuring step of using the measuring device can be selectively omitted.

In some embodiments of the present invention, on the cross section of the plasma delivered from the plasma generation volume to the support structure (or workpiece), the absorber in operation has at least one radial element which moves in the radial direction along the cross section. By modifying the position of the at least one radial element along the radial direction, the geometric configuration of the absorber on the cross section can be modified, so that the portion of plasma which would originally be absorbed by the absorber may be modified, and thus the distribution on the cross section of the plasma will be correspondingly modified.

In some embodiments of the present invention, at least two absorbers can be used at the same time, and on the cross section of the plasma delivered from the plasma generation volume to the support structure (or workpiece), the relative geometric relation of the absorbers is adjustable. Whether an absorber is fixed and other absorber is rotated and/or moved, all of the absorbers are relatively moved and/or rotated, or modified in the other ways. Thus, modifying the relative geometric relation of the absorbers is equal to modifying the overall geometric configuration of the absorbers on the plasma cross section, so that the portion of the plasma absorbed by the absorber can be modified, and then the distribution on the cross section of the plasma delivered to the workpiece (or the support structure) may be modified correspondingly.

It must be emphasized that the present invention is not limited to the details of the plasma-based processing system and the operation method thereof, and it only needs plasma to be generated in the plasma chamber, and the absorber to be used between the plasma generation volume inside the plasma chamber and the workpiece (or support structure) for adjusting the plasma, especially in adjusting the absorber according to the measurement result of the measuring device in measuring the plasma. Hence, except for the absorber, the other details and variations in the plasma-based processing system and the operation method thereof and the other processes for the ion implantation, etching, sputtering, and plasma enhanced chemical vapor deposition are omitted and not further described herein.

### BRIEF DESCRIPTION OF THE DRAWINGS

FIG. 1 illustrates a basic framework of the plasma-based processing system;

FIG. 2A to FIG. 2B illustrate the plasma-based processing system according to preferred two embodiments of the present invention;

FIG. 3A to FIG. 3B provide the plasma-based processing system operation method according to preferred two embodiments of the present invention;

FIG. 4A to FIG. 4C illustrate some embodiments of the present invention; and

FIG. 5A to FIG. 5F illustrate some embodiments of the present invention.

### DETAILED DESCRIPTION OF THE INVENTION

The detailed description of the present invention will be discussed in the following embodiments. These embodiments of the present invention are not intended to limit the scope of the invention, and they are suitable for other applications as well. The illustrations reveal a few details, but it should be understood that the design details of the disclosed elements may be different from the revealed ones, unless it is the situation that the characteristics of the elements are explicitly limited.

The present invention mainly uses one or a plurality of absorbers made of an electrical conductive material or electrical conductive materials. In the process of the plasma being delivered from the plasma generation volume of the plasma chamber to the workpiece (or the support structure for supporting the workpiece), a portion of the plasma will be absorbed for adjusting the distribution of the delivered plasma. More particularly, by changing the configuration of the absorber between the plasma generation volume and workpiece (or the support structure), it may change the absorbing/adjusting effect of the absorber for the delivered plasma, so that any possible uniform/non-uniform distribution of the plasma, delivered from the plasma generation volume, can be effectively adjusted. Furthermore, measuring the delivered plasma by the measuring device before using the absorber, the configuration of the absorber on the cross section of the delivered plasma may be adjusted according to the measured actual distribution of the delivered plasma, in order to enhance the accuracy and/or adjustment flexibility of using the absorber for adjusting the plasma distribution delivered on the workpiece.

Correspondingly, in order to simplify the drawings and discussions, all of the following description of the embodiments and drawings only focus on the plasma chamber, the measuring device, the absorber and the workpiece/support structure. The focus is particularly placed on the practical variations of absorber. In other words, most of the details of the plasma-based processing system and operation method thereof will be omitted.

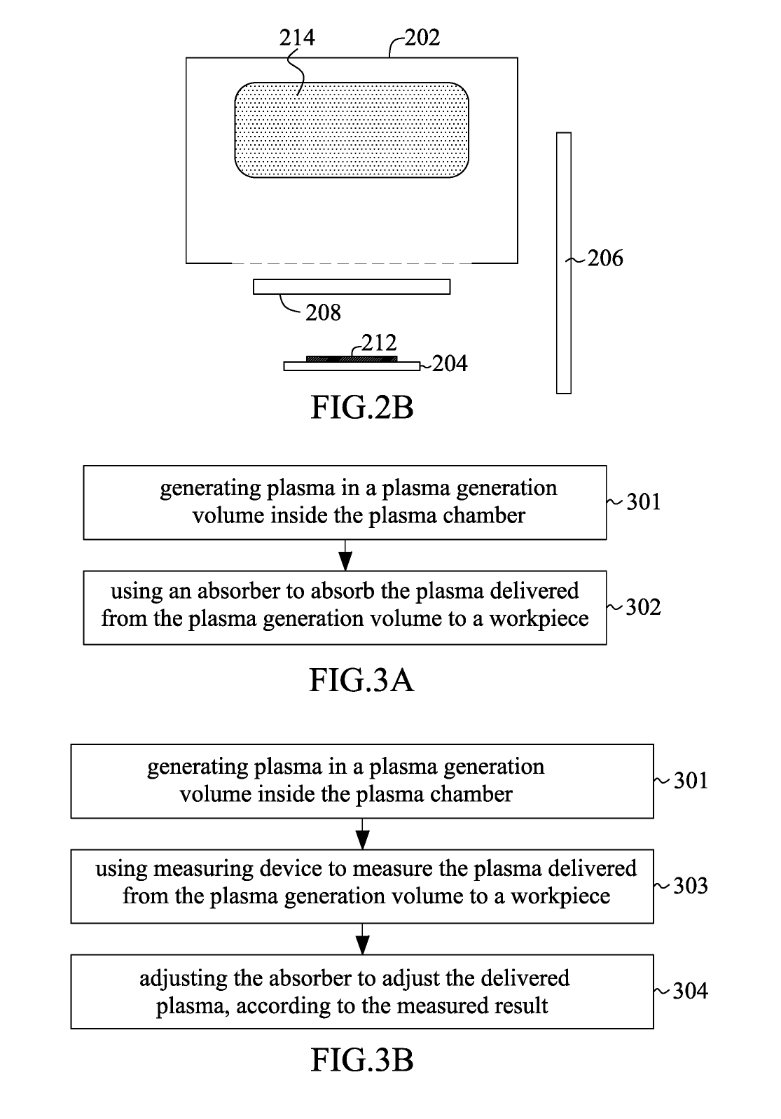

FIG. 2A and FIG. 2B illustrate a plasma-based processing system according to two embodiments of the present invention. The plasma chamber 202 is configured to generate plasma, the support structure 204 is configured to support the workpiece 212. The plasma usually will not spread all over the entire inner space of the plasma chamber 202, but will be formed and distributed on a portion of the inner space of the plasma chamber 202 (plasma generation volume). The support structure 204 may be disposed outside the plasma chamber 202 (as similar as the plasma base material modification system), and also can be disposed inside the plasma chamber 202 (as similar as the plasma enhanced chemical vapor deposition system) or be disposed on the chamber wall of the plasma chamber 202. The details of the support structure 204 are not limited, as long as it is capable of supporting or fixing the workpiece 212 to be processed by the plasma. The positions of the measuring device 206 and the absorber 208 are adjustable. Where there is a need to measure the plasma, the measuring device 206 can be moved to a position between the plasma generation volume and the support structure 204 for measurement. Where there is a need to adjust the absorber 208, the absorber 208 can be moved to a position between the plasma generation volume and support structure 204. The measuring device 206 and the absorber 208 can be moved to any position when there is no need to measure the plasma nor to adjust the absorber, as long as the placement of measuring device 206 and absorber 208 has no influence on the process of transferring the plasma from the plasma generation volume to the workpiece 212 or support structure 204.

It must be emphasized that the plasma chamber 202, support structure 204, measuring device 206 and absorber 208 only limit its functions without limiting its hardware details of any known and any developments in hardware which can be applied. Moreover, if the adjustments of absorber 208 are routine, well known, or can be directly determined according to the operating parameters of the plasma chamber, the use of measuring device 206 can be waived.

FIG. 3A and FIG. 3B illustrate a plasma-based processing system operation method according to two embodiments of the present invention. Firstly, as shown in step 301, the method generates the plasma in the plasma generation volume of the plasma chamber. Then, as shown in step 302, the method uses the absorber to adjust the plasma delivered from the plasma generation volume to the workpiece, or, as shown in step 303 and step 304, the method uses the measuring device to measure the plasma delivered from the plasma generation volume to the workpiece at first, and then adjust the absorber for adjusting the plasma according to the measurement result. The measuring device may be used to measure for only one time, and then the absorber can be correspondingly used for adjusting the delivered plasma one time. The measuring device can be used again for re-measuring the plasma one more time every period of time or when the plasma chamber is adjusted or the processed workpiece is changed, so as to correspondingly adjust the absorber again for adjusting the delivered plasma.

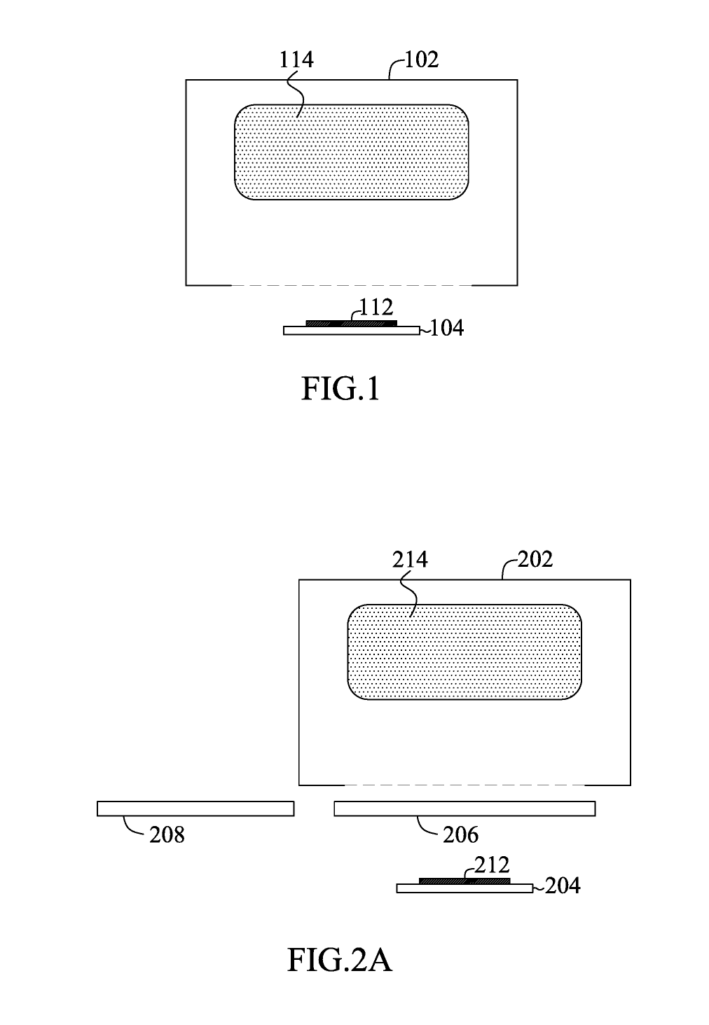

Compared to the basic framework of the plasma-based processing system shown in FIG. 1, a main change of the present invention is to use the absorber for adjusting the plasma delivered from the plasma generation volume to the workpiece or support structure. Further, the material of the absorber is electrically conductive material, such as metal or graphite. When the plasma and the absorber interact with each other, the charged particles of the plasma will be delivered through the electrical conductive material away from the plasma, so that the distribution of charged particles within the plasma (or the distribution of the current of ions of the plasma) will change correspondingly. Furthermore, as the absorber is used to take a portion of the charged particles away from the plasma for adjusting the plasma distribution, the area of the absorber must be smaller than the cross sectional area of the plasma which is perpendicular to the plasma transmission direction from the plasma generation volume toward the workpiece/supporting structure. Otherwise none of the plasma will be delivered to the workpiece/support structure. Also, the contour of the absorber often has at least one hole-patterned structure, so that different regions in the cross-section of plasma may be faced with the absorber of different spatial distribution of electrically conductive material. Hence, the absorbing percentages by the absorber in different cross-sectional regions of the plasma are constantly different, and in turn, the plasma distribution along the cross-section of the plasma varies or being modified by the interaction between the plasma and the absorber.

Furthermore, the actual operation of the plasma chamber is often hard to control precisely, and therefore the distribution of the plasma in the plasma generation volume may vary with time, even though the operation of the plasma chamber is not actively adjusted for changing the distribution of the plasma in the plasma generation volume. Also, the configuration of the plasma chamber, such as how to introduce and distribute the gas and energy in the plasma chamber, the geometric contour of the plasma chamber, the size and shape of outlet opening for the plasma and the others often will affect the distribution of the plasma delivered from the plasma generation volume to the workpiece/support structure. Thus, for one purpose of adjusting the plasma distribution delivered to the workpiece in accordance with the variation of the plasma distribution in the plasma generation volume, and another purpose of adjusting the plasma distribution delivered to the workpiece to comport with various possible plasma distributions generated in the plasma generation volume, the absorber may be flexibly adjusted.

In some embodiments of the present invention, the absorber has one or a plurality of radial elements. The radial elements can move in the radial direction along the cross section of the plasma delivered from the plasma generation volume to the workpiece/support structure. It is usual that the radial element is positioned on the edge of the cross section of the plasma, and the distance between the radial element and the center of the cross section of the plasma can be adjusted along the radial direction. Hence, by moving the radial element towards the center of the cross section of the plasma along the radial direction, the interaction between the absorber and the plasma can be enhanced, so as to increase the plasma absorbed by the absorber. Hence, by moving the radial element away from the center of the cross section of the plasma along the radial direction, the interaction between the absorber and the plasma can be reduced, so as to decrease the plasma absorbed by the absorber. Especially, as the ion concentration of the plasma generated in the plasma generation volume often is high around the center part and is low around the peripheral part, by using radial elements to reduce/eliminate the concentration variation between the central part and the peripheral part of the plasma, the plasma on the workpiece can be more uniform and stable.

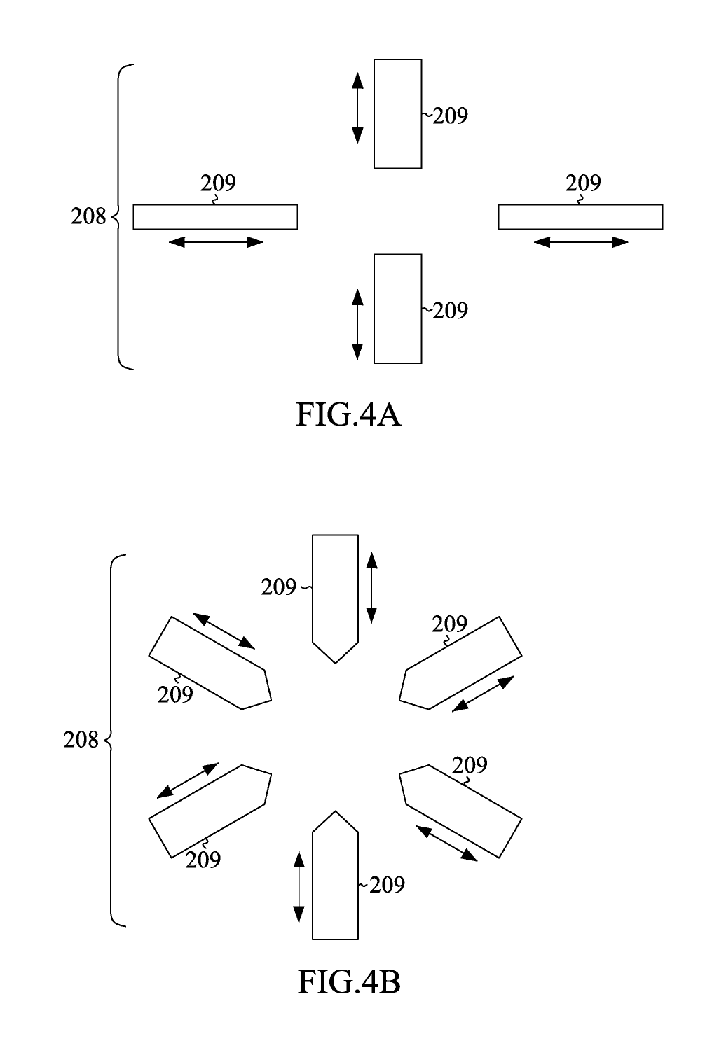

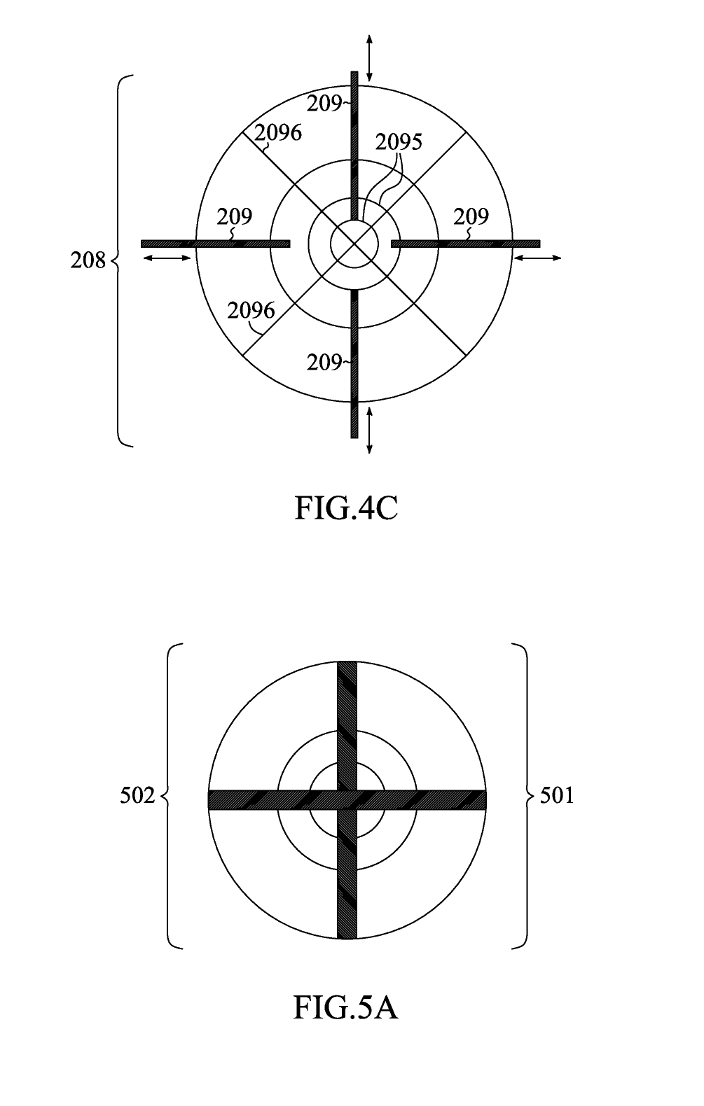

The radial elements illustrated in various embodiments of the present invention can be different in contours, positions and quantities. In some embodiments, as shown in FIG. 4A, on the cross section of the plasma delivered from the plasma generation volume to the support structure, the absorber 208 may have four radial elements 209, which move in the radial direction along the cross section, and the angle between any two adjacent radial elements 209 is 90 degrees. In addition, in some embodiments not specifically illustrated, the absorber 208 may have N radial elements 209, which move in the radial direction along the cross section, and the angle between any two adjacent radial elements 209 is 360/N degrees, and N is a positive integer greater than zero. Further, in some embodiments not specifically illustrated, the absorber 208 may have a plurality of radial elements 209, which move in the radial direction along the cross section, and the angles between each two adjacent radial elements 209 may be different with one another.

Moreover, in some embodiments not specifically illustrated, the absorber 208 may have one or a plurality of radial elements 209 which move in the radial direction along the cross section, and at least one radial element 209 can move in the direction along the arc. That is to say, the radius of the radial element on the cross section can be adjusted.

In addition, in some embodiments not specifically illustrated, on the cross section of the plasma delivered from the plasma generation volume to the support structure, the absorber 208 has at least two radial elements 209, and any two radial elements 209 have exactly the same size and contour. Moreover, in some embodiments not specifically illustrated, the absorber 208 has at least two radial elements 209 aligned in a line along the cross section of the plasma delivered from the plasma generation volume to the support structure, wherein the distance between the center of the cross section of plasma and the terminal end of each of the two radial elements 209 is identical. Further, in some embodiments not specifically illustrated, the absorber 208 between the cross section of plasma and the support structure has at least two radial elements 209, and the distances between the two radial elements 209 along the radial direction and the center of the cross section of plasma are the same. Herein, FIG. 4B illustrates one embodiment of the present invention with six radial elements 209, which have the features mentioned in above embodiments.

In addition, in some embodiments not specifically illustrated, on the cross section of the plasma delivered from the plasma generation volume to the support structure, the absorber 208 has at least two radial elements 209, and the distance between any radial element 209 and the center of the cross section of the plasma can be adjusted along the radial direction. In other words, each radial element 209 can be adjusted individually, in order to comport with any possible distributions of the plasma delivered from the plasma generation volume.

Furthermore, in some embodiments not specifically illustrated, on the cross section of the plasma delivered from the plasma generation volume to the support structure, the absorber 208 not only has at least one radial element, but also has at least one fixed arc-shaped member and at least one fixed cylindrical element, as shown in FIG. 4C, which includes at least two concentric rings (2095), the pillars (2096) connected with the concentric rings and the movable radial elements (209). Hence, the different parts of the absorber 208 may respectively have different electrical conductive space distributions, and that is to say, there are various absorbing percentage of absorbing the charged particles in the plasma, so that the adjustment of the absorber 208 for the plasma distribution can be more comprehensive.

In other embodiments of the present invention, at least two absorbers exist between the plasma generation volume and the support structure. Herein, the contour of any one of the absorbers may have at least one hole-patterned structure, and on the cross section of the plasma delivered from the plasma generation volume to the workpiece, the relative geometric relation of these absorbers can be modified. As the plasma from the plasma generation volume will interact with each of the absorbers at first and then be delivered to the workpiece, and the combination of these absorbers is equal to an equivalent absorber. Thus, changing the relative geometric relation of these absorbers is equal to changing the contour of this equivalent absorber, so that the adjusted plasma distribution of the equivalent absorber can be changed correspondingly.

There is no need to limit the details of each absorber, as the main feature of these embodiments is to flexibly combine two or more absorbers to adjust the space distribution of the electrical conductor that occurs when the plasma is delivered from the plasma generation volume to the workpiece. Yet in different embodiments, there can be at least two absorbers with completely identical or different patterned structures on the cross section of the plasma delivered from the plasma generation volume to the workpiece/support structure. The patterned structure of any absorber can be made up of one or a plurality of members either distributed along the radial direction or distributed along the arc-shaped direction. The patterned structure of any absorbers can be made up of a plurality of linear strings and a plurality of concentric ring as well. Of course the patterned structure may contain other configurations which are not specifically described herein.

In different embodiments, the at least two absorbers may be combined in many different ways. In some embodiments, on the cross section of the delivered plasma, at least one absorber is fixed, and at least one absorber is rotatable or movable. Further, on the cross section of the delivered plasma, the centers of at least two absorbers are concentric while in other embodiments, the centers of at least two absorbers are eccentric. In some embodiments, even along the direction from the plasma generation volume to the workpiece/support structure, the at least two absorbers are overlapped with each other. It may be either partially overlapped or completely overlapped. In some embodiments, none of the absorbers is overlapped.

Obviously, by varying how different absorbers overlap, deciding whether different absorbers overlap or not, and varying the relative rotation angle, moving direction and moving distance between the absorbers, many different kinds of equivalent absorbers can be realized by adjusting a few absorbers, and many different adjustment effects for the delivered plasma can be generated. Therefore, these embodiments can provide a simple, low-cost and efficient adjustment method for the delivered plasma.

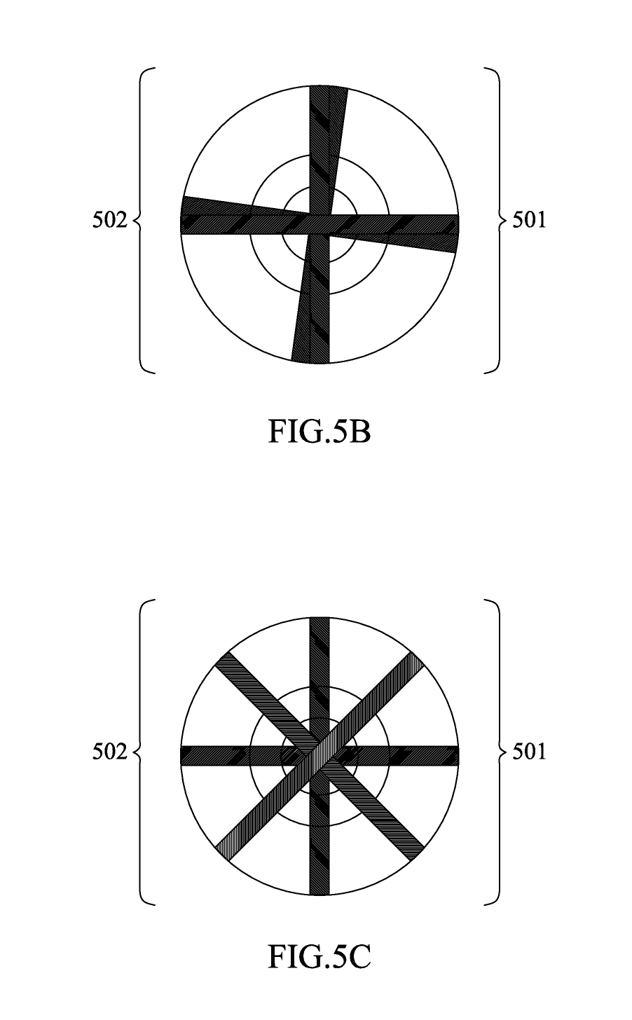

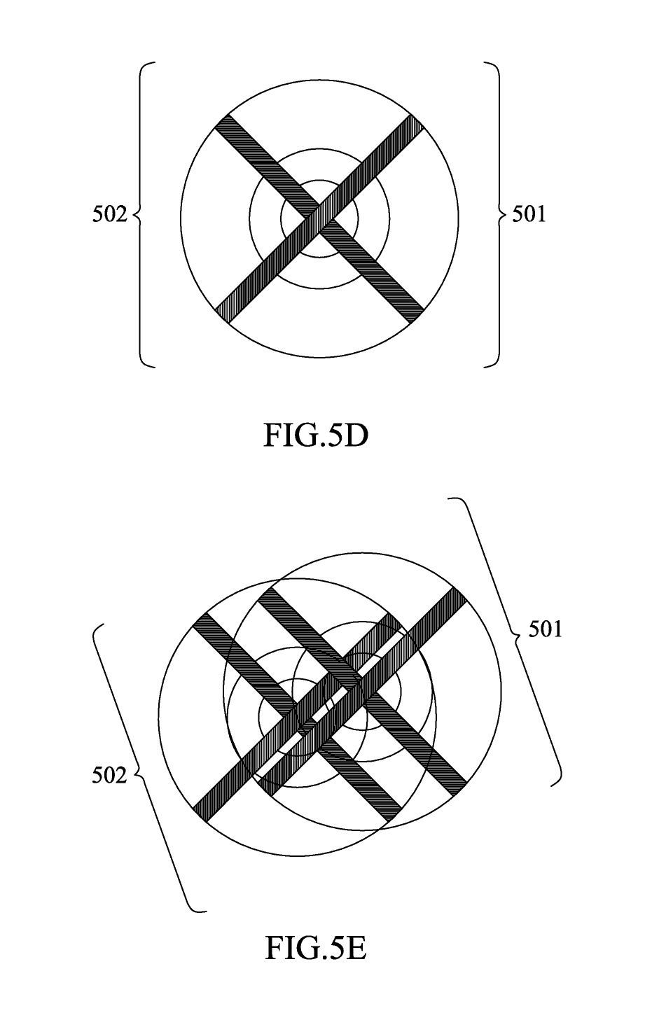

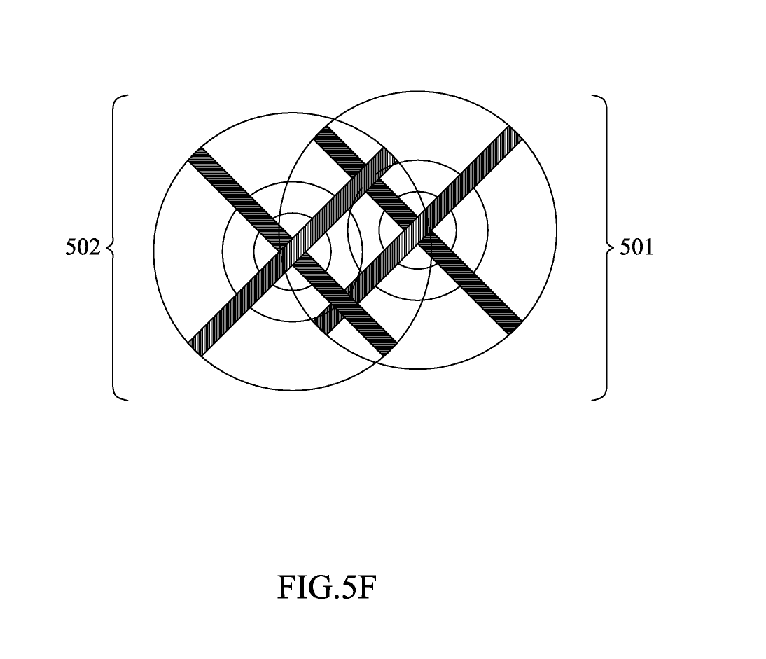

FIG. 5A to FIG. 5F illustrate two examples of using a plurality of absorbers to adjust the plasma. Herein, both of two examples use two substantially identical absorbers 501/502, and each absorber is made up of a plurality of concentric members and two linear members which are perpendicular to each other. FIG. 5A shows an equivalent absorber consisting of these two absorbers 501/502 completely overlapped, FIG. 5B shows an equivalent absorber consisting of these two absorbers 501/502 which have a relative rotation of a smaller angle, and FIG. 5C shows an equivalent absorber consisting of these two absorbers 501/502 which have a relative rotation of a larger angle. FIG. 5D shows an equivalent absorber consisting of these two absorbers 501/502 which are completely overlapped, FIG. 5E shows an equivalent absorber consisting of these two absorbers 501/502 which have a smaller relative distance with each other, and FIG. 5F shows an equivalent absorber consisting of these two absorbers 501/502 which have a larger relative distance with each other. The two absorbers 501/502 can both relatively rotate or move at the same time, or even these two absorbers 501/502 may respectively have different patterned structure.

It should be added that portions of the cross section of the transmitted plasma (positions corresponding to the ones where the absorbers lie on the cross section of the transmitted plasma) will obviously lack of or even have no charged particles. This is because the absorbers will absorb and direct the charged particles away from the plasma when the plasma being transmitted along the transmission direction passes through the absorbers and is adjusted by the same. However, due to the interactions among the large number of charged particles within the plasma, charged particles from the rest portions on the cross section of the transmitted plasma will gradually move into the afore-mentioned devoid portions. Accordingly, as long as the distance between the absorber and the workpiece supported by the support structure is sufficient, the projected distribution of the cross section of the delivered plasma on the workpiece will be a more uniform distribution.

Although specific embodiments have been illustrated and described, it will be appreciated by those skilled in the art that various modifications may be made without departing from the scope of the present invention, which is intended to be limited solely by the appended claims.

1. A plasma-based processing system, comprising:
a plasma chamber, configured to generate plasma in a plasma generation volume inside the plasma chamber;
a support structure, configured to support a workpiece; and
an absorber, positioned between the plasma generation volume and the support structure, and configured to absorb a portion of the plasma delivered from the plasma generation volume to the support structure; and
wherein, on a cross section of the plasma delivered from the plasma generation volume to the support structure, the absorber has at least one radial element being able to move in a radial direction along the cross section; and
wherein the absorber is made of electrical conductive material.

2. The system of claim 1, wherein the support structure is positioned outside the plasma chamber.

3. The system of claim 1, wherein a contour of the absorber has at least one hole-pattern structure.

4. The system of claim 1, on the cross section of the plasma delivered from the plasma generation volume to the support structure, the absorber has N radial elements, which move in the radial direction along the cross section, and each angle between any two adjacent radial elements is 360/N degrees, and N is a positive integer greater than zero.

5. The system of claim 1, wherein, on the cross section of the plasma delivered from the plasma generation volume to the support structure, the absorber has at least two radial elements, and any two of the radial elements have exactly the same size and contour.

6. The system of claim 1, wherein, on the cross section of the plasma delivered from the plasma generation volume to the support structure, the absorber has at least two radial elements, and a distance between any terminal end of the two radial elements positioned in a straight line and a center of the cross section is identical.

7. The system of claim 1, wherein, on the cross section of the plasma delivered from the plasma generation volume to the support structure, the absorber has at least two radial elements, and a distance between any of the radial elements and a center of cross section is individually adjustable along a radial direction.

8. The system of claim 1, wherein, on the cross section of the plasma delivered from the plasma generation volume to the support structure, the absorber has at least two radial elements, and a distance between any of the radial elements along a radial direction and a center of cross section is identical.

9. The system of claim 1, wherein, on the cross section of the plasma delivered from the plasma generation volume to the support structure, the absorber has at least one arc-shaped member.

10. The system of claim 1, wherein, on the cross section of the plasma delivered from the plasma generation volume to the support structure, the absorber has at least two concentric rings.

11. A plasma-based processing system, comprising:
a plasma chamber, configured to generate plasma in a plasma generation volume inside the plasma chamber;
a support structure, configured to support a workpiece; and
at least two absorbers, positioned between a plasma generation volume and a support structure, and configured to absorb a portion of plasma delivered from the plasma generation volume to the support structure; and
wherein a contour of each absorber has at least one hole-pattern structure;
wherein material of each absorber is electrical conductive material; and
wherein, on a cross section of the plasma delivered from the plasma generation volume to the support structure, a relative geometric relation of the absorbers is adjustable.

12. The system of claim 11, wherein the support structure is positioned outside the plasma chamber.

13. The system of claim 11, wherein, on the cross section of the plasma delivered from the plasma generation volume to the support structure, at least two absorbers have an exactly the same pattern structure.

14. The system of claim 11, wherein, on the cross section of the plasma delivered from the plasma generation volume to the support structure, the pattern structures of any two of absorbers are different.

15. The system of claim 11, wherein, on the cross section of the plasma delivered from the plasma generation volume to the support structure, at least one absorber is fixed, and at least one absorber is rotatable.

16. The system of claim 11, wherein, on the cross section of the plasma delivered from the plasma generation volume to the support structure, centers of the at least two absorbers are overlapped.

17. The system of claim 11, wherein, on the cross section of the plasma delivered from the plasma generation volume to the support structure, at least one absorber is fixed, and at least one absorber is movable.

18. The system of claim 11, wherein, on the cross section of the plasma delivered from the plasma generation volume to the support structure, centers of the absorbers are separated.

19. The system of claim 11, wherein, on the cross section of the plasma delivered from the plasma generation volume to the support structure, at least one absorber has at least one radial element and at least one arc-shaped member.

20. The system of claim 11, wherein, on the cross section of the plasma delivered from the plasma generation volume to the support structure, at least one absorber has at least one radial element and at least two concentric rings.

21-35. (canceled)
